(19) United States
(12) Patent Application Publication
(10) Pub. No.: US 2024/0281497 A1
(43) Pub. Date: Aug. 22, 2024

(54) SRAM MATRIX MULTIPLICATION NETWORK

(71) Applicant: Rain Neuromorphics Inc., San Francisco, CA (US)

(72) Inventors: Jack David Kendall, San Mateo, CA (US); Mohammed Elneanaei Abdelmoneem Fouda, Irvine, CA (US)

(21) Appl. No.: 18/444,406

(22) Filed: Feb. 16, 2024

Related U.S. Application Data
(60) Provisional application No. 63/446,761, filed on Feb. 17, 2023.

(51) Int. Cl. G06F 17/16; H10B 10/00

(52) U.S. Cl. CPC G06F 17/16; H10B 10/00

(57) ABSTRACT

A resistive cell is described. The resistive cell includes static random access memory (SRAM) cells, a digital-to-analog converter (DAC), and a transistor network. The SRAM cells have a multi-bit state. The DAC converts the multi-bit state to an analog signal. The transistor network receives the analog signal as an input and provides a digitally controlled conductance. The resistive cell is integrated into a matrix multiplication network.

### CROSS REFERENCE TO OTHER APPLICATIONS

This application claims priority to U.S. Provisional Patent Application No. 63/446,761 entitled SRAM FAST SYSTEM OF EQUATIONS SOLVER filed Feb. 17, 2023 which is incorporated herein by reference for all purposes.

### BACKGROUND OF THE INVENTION

Matrix multiplications have wide applicability. For example, a system of equations may be represented in the format AX=B, where X is a vector of variables, B is the resultant and A is a matrix of coefficients for the variables. The matrix multiplication AX expresses the system of equations. Similarly, the matrix multiplication A⁻¹B=X, where A⁻¹ is the inverse of matrix A, solves the system of equations (i.e. determines the values of the elements of the vector X for given outputs represented by B). Such matrix multiplications, and the corresponding system of equations, may be used in a variety of real-world applications. For example, in modified nodal analysis (MNA), the conductances of components of a circuit are linearized and represented in a matrix. The matrix may then be used to mathematically predict the behavior of a circuit (e.g., in the example above, A—also termed G or M in the context of MNA—may be the MNA/conductance matrix, X may be the voltages at the inputs, and B may be the currents at the outputs). In this case, A⁻¹B may be used to determine the input voltages (X) that result in the known output currents (B). In the context of machine learning, layers of weights (e.g. impedances) may be represented by a matrix. In this context, A is the matrix of weights, X are the voltages input to the weight layer (e.g. from a previous neuron layer), and B is the output of the weight layer. Also in this example, A⁻¹B may be used to determine how to adjust the value of the weights given a loss function (i.e., B) that undergoes backpropagation through the learning network for given inputs (X).

Although matrices may have wide applicability, computations involving matrices may be time consuming in computer systems. For example, computing the inverse of a matrix is order O(n³), where n is the input size, in complexity. Thus, for a large matrix (e.g., a large number of conductances in an MNA matrix or a large number of weights in a learning network), determining the inverse of the matrix may be time consuming and/or require a significant expenditure of resources. Consequently, techniques for improving the ability of computing systems to be used in the context of solving problems involving matrix multiplications are desired.

### BRIEF DESCRIPTION OF THE DRAWINGS

Various embodiments of the invention are disclosed in the following detailed description and the accompanying drawings.

FIG. 1 depicts an embodiment of a system for performing matrix multiplications using resistive SRAM cell(s) in a matrix multiplication network.

FIG. 2 depicts an embodiment of a multi-state resistive SRAM cell usable in a matrix multiplication network.

FIG. 3 depicts an embodiment of a system for performing matrix multiplications using resistive SRAM cell(s) in a matrix multiplication network.

FIG. 4 depicts an embodiment of a system for performing matrix multiplications using resistive SRAM cell(s) in a matrix multiplication network.

FIG. 5 depicts an embodiment of a system for performing matrix multiplications using resistive SRAM cell(s) in a matrix multiplication network.

FIG. 6 depicts an embodiment of a system for performing matrix multiplications using resistive SRAM cell(s) in a matrix multiplication network.

FIG. 7 is a flow chart depicting an embodiment of a method for performing matrix multiplications using resistive SRAM cell(s) in a matrix multiplication network.

FIG. 8 is a flow chart depicting an embodiment of a method for performing a matrix inversion using resistive SRAM cell(s) in a matrix multiplication network.

FIG. 9 is a flow chart depicting an embodiment of a method for performing matrix multiplications using resistive SRAM cell(s) in a matrix multiplication network.

FIG. 10 depicts an embodiment of a system for performing matrix multiplications using resistive SRAM cell(s) in a matrix multiplication network to iterative solve a system of equations.

### DETAILED DESCRIPTION

The invention can be implemented in numerous ways, including as a process; an apparatus; a system; a composition of matter; a computer program product embodied on a computer readable storage medium; and/or a processor, such as a processor configured to execute instructions stored on and/or provided by a memory coupled to the processor. In this specification, these implementations, or any other form that the invention may take, may be referred to as techniques. In general, the order of the steps of disclosed processes may be altered within the scope of the invention. Unless stated otherwise, a component such as a processor or a memory described as being configured to perform a task may be implemented as a general component that is temporarily configured to perform the task at a given time or a specific component that is manufactured to perform the task. As used herein, the term ‘processor’ refers to one or more devices, circuits, and/or processing cores configured to process data, such as computer program instructions.

A detailed description of one or more embodiments of the invention is provided below along with accompanying figures that illustrate the principles of the invention. The invention is described in connection with such embodiments, but the invention is not limited to any embodiment. The scope of the invention is limited only by the claims and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

A resistive cell is described. The resistive cell includes static random access memory (SRAM) cells, a digital-to-analog converter (DAC), and a transistor network. The SRAM cells have a multi-bit state. The DAC converts the multi-bit state to an analog signal. The transistor network receives the analog signal as an input and provides a digitally controlled conductance. The resistive cell is integrated into a matrix multiplication network. In some embodiments, a gate of a transistor in the transistor network is coupled to a DAC output of the DAC. The DAC output provides the analog signal to the gate such that the analog signal controls the digitally controlled conductance.

In some embodiments, the matrix multiplication network is represented by a matrix. The matrix may include a modified nodal analysis (MNA) matrix for a corresponding network. The SRAM cells store a digital representation of the conductance for the MNA matrix of a component in the corresponding network. The matrix multiplication network may further include inputs, outputs, and feedback between the outputs and the inputs. A portion of the matrix corresponds to the feedback and is an invertible matrix. The corresponding network is a layer of a neural network. The layer includes a weight layer.

In some embodiments, the matrix multiplication network includes a crossbar network. The resistive cell is at a crossing point of the crossbar network. The matrix multiplication network may further include multiple resistive cells. Each of the resistive cells corresponds to the resistive cell and is located at the remaining crossing points of the crossbar network. In some such embodiments, the matrix multiplication network further includes inputs to the crossbar network, outputs from the crossbar network, and negative feedback networks coupling the outputs with the inputs. The negative feedback networks may be represented by at least one invertible matrix. The negative feedback networks include a plurality of operational amplifiers.

A system is described. The system includes inputs, resistive cells, and outputs. Each of the resistive cells includes SRAM cells having a multi-bit state, a DAC that converts the multi-bit state to an analog signal, and a transistor network receiving the analog signal as an input and provides a digitally controlled conductance. The resistive cells are between the inputs and the outputs. The inputs, the outputs and the resistive cells are configured as a matrix multiplication network.

In some embodiments, the matrix multiplication network represents a matrix. The multi-bit state of each of at least a portion of the resistive cells corresponds to a conductance in a modified nodal analysis (MNA) matrix for a corresponding network. The matrix multiplication network may further include feedback between the outputs and the inputs. A portion of the matrix corresponds to the feedback and is an invertible matrix. In some embodiments, the corresponding network is a layer of a neural network including multiple layers, The layer may include a weight layer. In some embodiments, the resistive cells are coupled as a crossbar network. Each of the resistive cells is at a crossing point of multiple crossing points of the crossbar network. In some embodiments, the system also includes negative feedback networks coupled between the outputs and the inputs, The negative feedback networks are represented by at least one invertible matrix.

A method is described. The method includes providing an input vector to inputs of a matrix multiplication network. The matrix multiplication network includes the inputs, resistive cells, and outputs. The resistive cells are coupled between the inputs and the outputs. Each resistive cell includes SRAM cells, a DAC, and a transistor network. The SRAM cells each have a multi-bit state. The DAC converts the multi-bit state to an analog signal. The transistor network receives the analog signal as an input and provides a digitally controlled conductance. The method also includes measuring, at the outputs, an output vector. The output vector is a product of a matrix and the input vector. In some embodiments, the resistive cells are coupled as a crossbar network. Each of the resistive cells is at a crossing point of a plurality of crossing points of the crossbar network.

In some embodiments, the matrix multiplication network also includes feedback networks coupled between the inputs and the outputs. The multi-bit state of each of the resistive cells corresponds to an element of the matrix. The output vector solves a system of equations represented by AX=B, where A is the matrix and B is the input vector. In some embodiments, the matrix multiplication network further includes feedback networks coupled between the inputs and the outputs such that the multi-bit state of each of the plurality of resistive cells corresponds to an element of the matrix and the input vector is one of a plurality of input vectors. In some such embodiments, the method may further include repeating the providing and measuring for each remaining vector of the plurality of input vectors. Each of the input vectors corresponds to a column in an identity matrix.

Although described in terms of certain electrical properties, one of ordinary skill in the art will recognize that other analogous properties may be used in an analogous system. Thus, although the techniques are described in terms of one or more of voltages, currents, impedances, admittances, conductances, and resistances, other analogous terms may be used. For example, embodiments described in the context of voltages are analogous to or may be described in the context of currents. Similarly, embodiments described in the context of conductances may be understood in the context of admittances and/or impedances. Further, various features are highlighted in the drawings. These features may be combined in manners not explicitly shown in the drawings.

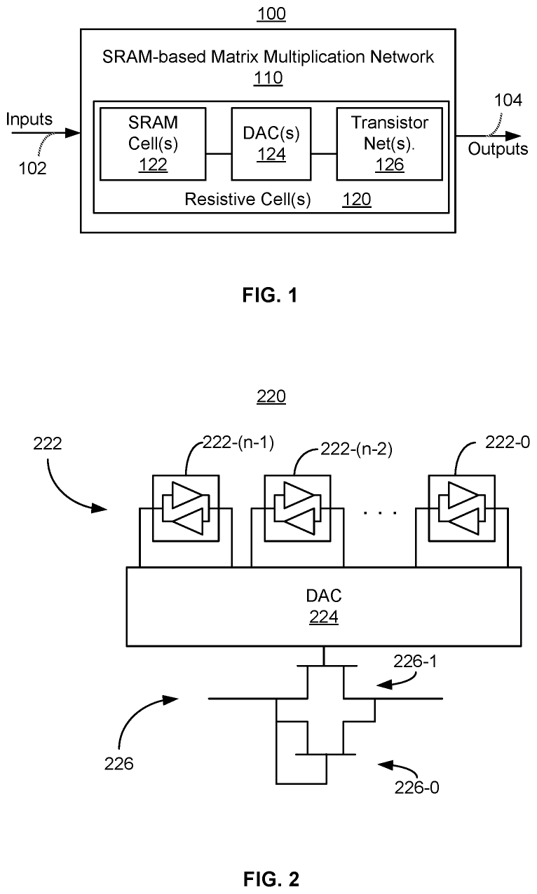

FIG. 1 depicts an embodiment of system 100 for performing matrix multiplications using resistive SRAM cell(s) in a matrix multiplication network. System 100 includes inputs 102, matrix multiplication network 110, and outputs 104. For simplicity, only certain portions of system 100 are shown. Additional and/or other components may be present. Although inputs 102 and outputs 104 are shown as a single line, in general, there are multiple inputs 102 for receiving multiple input signals and multiple outputs 104 for providing multiple outputs signals.

Matrix multiplication network 110 includes resistive cells 120, which store multiple bits. Stated differently, each resistive cell 120 has a multi-bit state. Resistive cells 120 use SRAM cell(s) 122 for storing multiple bits. Thus, resistive cell(s) 120 are also termed resistive SRAM cell(s) 120. Resistive SRAM cell(s) 120 include SRAM cell(s) 122, digital-to-analog converter(s) (DAC(s)) 124, and transistor network(s) 126. In some embodiments, a resistive SRAM cell 120 stores two or more bits. Resistive SRAM cells 120 store data corresponding to the matrix for which mathematical operations such as matrix multiplications are desired to be performed. Stated differently, resistive SRAM cells 120 store values that for the element(s) of the matrix. In some embodiments, the matrix (or portion thereof) to be operated on using matrix multiplication network 110 is only in resistive SRAM cell(s) 120. In some embodiments, a portion (e.g. one or more elements) of the matrix to be multiplied by system 100 is stored in resistive SRAM cell(s) 120, while remaining portions of the matrix are stored in another manner. In some embodiments, matrix multiplication network 110 is a crossbar array having resistive cells at the crossings. However, other configurations are possible. Inputs 102 receive signals that for elements of the vector which may be multiplied by the matrix stored in matrix multiplication network 110. Outputs provide the output vector resulting from the multiplication performed using matrix multiplication network 110.

In operation, the elements of an input vector are provided to inputs 102 as input signals. Matrix multiplication network 110 multiplies the vector with the matrix stored in, e.g., resistive cell(s) 120. The elements of the vector provided to inputs 102 are multiplied with the appropriate elements of the matrix stored in resistive SRAM cell(s) 120. To do so, the binary data stored in SRAM cell(s) 122 is converted, via DAC(s) 124 and transistor network(s) 126, to analog representations of the matrix elements and multiplied by the input signals corresponding to the elements of the input vector. The resulting vector is provided as output signals on outputs 104.

Thus, using system 100, a vector matrix multiplication can rapidly be performed in hardware using a matrix stored as binary data in SRAM cell(s) 122. Further, use of SRAM cell(s) 122 allows for improved scalability and ease of manufacture. As a result, a vector matrix multiplication may be more rapidly and easily performed.

FIG. 2 depicts an embodiment of multi-state resistive SRAM cell 220 usable in a matrix multiplication network, such as matrix multiplication network 110. Thus, resistive SRAM cell 220 may replace a resistive SRAM cell 120. Resistive SRAM cell 220 includes SRAM cells 222-0 through 222-(n-1) (collectively or generally SRAM cell(s) 222), DAC 224, and transistor network 226 that may be considered to be analogous to SRAM cell(s) 122, DAC(s) 124, and one of transistor network(s) 126, respectively. Resistive SRAM cell 220 stores n bits. Because SRAM cells 222 store binary data, there are n SRAM cells 222 used to store n bits. SRAM cells 222 are coupled with DAC 224.

DAC 224 converts the n bits stored in SRAM cells 222 to a voltage. DAC 224 is coupled with transistor network 226 that includes two transistors 226-0 and 226-1 (collectively or generically transistors 226). The voltage provided by DAC 224 to the gate of transistor 226-1 controls the conductance of transistor network 226. More specifically, the voltage output by DAC 224, V_{DAC}, may be:

$${V}_{D A C} = {V}_{0} + Δ V {\sum }_{i = 0}^{n - 1} {b}_{i} {2}^{i}$$

$$Δ V = ( {V}_{r e f}^{0} - {V}_{0} ) / {2}^{n}$$

Where V₀ is a voltage offset of DAC224, n is the precision of DAC 224, V_{ref} is the reference voltage, and bᵢ is the data stored in i^{th} SRAM cell 222-i. In the embodiment shown, DAC 224 is a current steering DAC for simplicity of design and efficiency of area use.

In the embodiment shown, transistors 226 are CMOS transistors. Transistors 226 are also desired to be operated in their linear range in order to improve control over the resulting conductance. Further, transistors 226 provide a positive conductance. For the embodiment shown, the following may provide for this operation. The equivalent conductance of transistor network 226, G_{eq}, is k(V_{C}−2 Vₜₕ), where Vₜₕ is the threshold voltage of transistors 226, V_{C} is the voltage input to the gate of transistor 226-1, and k is a parameter related to transistors 226. However, the input voltage to the gate of transistor 226-1 is V_{DAC}. Given the value of V_{DAC} above, the conductance of transistor network 226 is:

$${G}_{e q} = k ( {V}_{0} - 2 {V}_{t h} + Δ V {\sum }_{i = 0}^{n - 1} {b}_{i} {2}^{i} )$$

where Vₜₕ is the threshold voltage of transistors 226 and k is a parameter related to transistors 226. For a non-negative conductance to be assured, V₀>2Vₜₕ. For transistors to operate in the linear range, the source-drain voltage (VDs) is less than the source-gate voltage (V_{GS}) minus the threshold voltage (Vₜₕ). In some embodiments, the source is grounded to sense the current. Thus, the voltage input, Vin, is less than or equal to the voltage DAC 224 input to the gate of transistor 226 minus the threshold voltage (Vᵢₙ≤V_{DAC}−Vₜₕ). Given the definition of V_{DAC} above, this corresponds to the maximum voltage for Vᵢₙ=Vₜₕ.

In operation, the bits stored in SRAM cells 222 are provided to DAC, which converts the digital multi-bit signal to an analog signal (e.g. an analog voltage, V_{DAC}). The voltage provided from DAC 224 to the gate of transistor 226-1 controls the conductance (and thus impedance) of transistor network 226. This controlled impedance corresponds to the data stored in SRAM cells 222 and, therefore, the value of the matrix element (or other data) stored in resistive SRAM cell 220. SRAM resistance cell 220 thus provides a digitally controlled conductance based on the binary data stored in SRAM cells 222.

Using resistive SRAM cell 220, for example in matrix multiplication network 110 of system 100, allows for data corresponding to a matrix (e.g. an element of the matrix) to be digitally stored in SRAM cells 222. A network incorporating resistive SRAM cell 220 may have enhanced scalability and may be simpler to fabricate. The vector matrix multiplication network incorporating resistive SRAM cell 220 may rapidly perform matrix multiplications and other operations on a matrix stored as binary data in SRAM cell(s) 222 of the resistive SRAM cells 220 used. As a result, a vector matrix multiplication may be more rapidly and easily performed. Moreover, SRAM cells 220 may be programmed more quickly than other emerging device-based architectures.

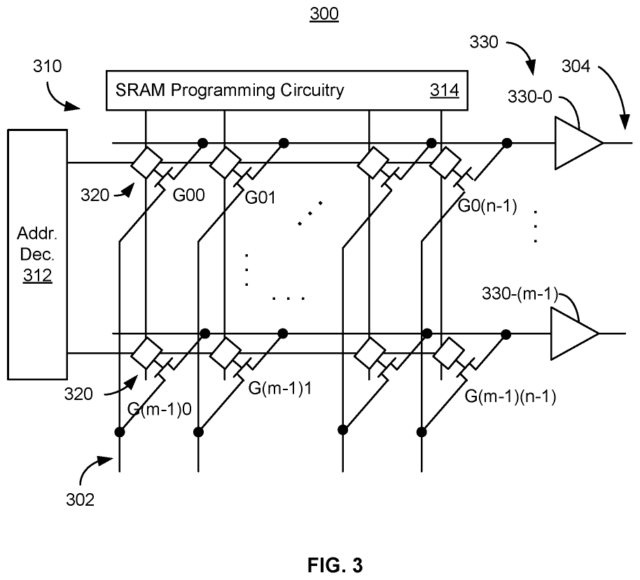

FIG. 3 depicts an embodiment of system 300 for performing matrix multiplications using resistive SRAM cell(s) in a matrix multiplication network. System 300 is analogous to system 100. Thus, system 300 includes inputs 302, outputs 304, and matrix multiplication network 310 incorporating resistive SRAM cells 320 analogous to inputs 102, outputs 104, and matrix multiplication network 110 and resistive SRAM cells 120. Each resistive SRAM cell 320 may be analogous to resistive SRAM cell 220. Thus, each SRAM cell 320 (of which only two are labeled) may include a number of SRAM cells for storing binary data having a desired number of bits, at least one DAC, and a transistor network analogous to SRAM cells 222, DAC 224, and transistor network 226.

Matrix multiplication network 310 includes address decoder 312, SRAM programming circuitry 314, resistive SRAM cells 320, output amplifiers 330-0 through 330-(m-1) (collectively or generically output amplifiers 330), and lines corresponding to inputs 302 and outputs 304. Address decoder 312 selects resistive SRAM cells 320. SRAM programming circuitry 314 programs the matrix elements into each of the resistive SRAM cells 320. In the embodiment shown, SRAM programming circuitry 314 performs this programming row by row. Output amplifiers 330 are transimpedance amplifiers in some embodiments. The lines corresponding to inputs 302, outputs 304, and resistive SRAM cells 320 may form a crossbar. Thus, matrix multiplication network 310 is a crossbar network. For clarity, in FIG. 3 transistors G00 through G(m-1)(n-1) (collectively or generically transistor(s) Gᵢⱼ) are shown separately from the remainder of resistive SRAM cells 320 (which are indicated by a box). Transistors Gᵢⱼ may correspond to transistor 226-0 shown in resistive SRAM cell 220. In addition, Gᵢⱼ corresponds to the effective impedance of the transistor network for resistive SRAM cell 320.

In operation, an input vector is provided via inputs 302. Address decoder 312 activates the lines for resistive SRAM cells 320. The conductance developed on the transistor network for each SRAM cell 320 is combined with the corresponding input signal from the input vector and provided to output amplifiers 330. Output amplifiers 330 convert the currents provided from the crossbar to voltages. The resultant of the input vector multiplied by the matrix stored in resistive SRAM cells 320 is output via outputs 304. Thus, an output vector that is the input vector multiplied by the matrix stored in matrix multiplication network 310 may be provided.

Using system 300, a vector matrix multiplication can rapidly be performed in hardware using a matrix stored as binary data in resistive SRAM cell(s) 320. Further, use of resistive SRAM cell(s) 320 allows for improved scalability and case of manufacture. SRAM cells 320 also provide faster programming than other emerging device-based architectures. As a result, a vector matrix multiplication may be more rapidly and easily performed.

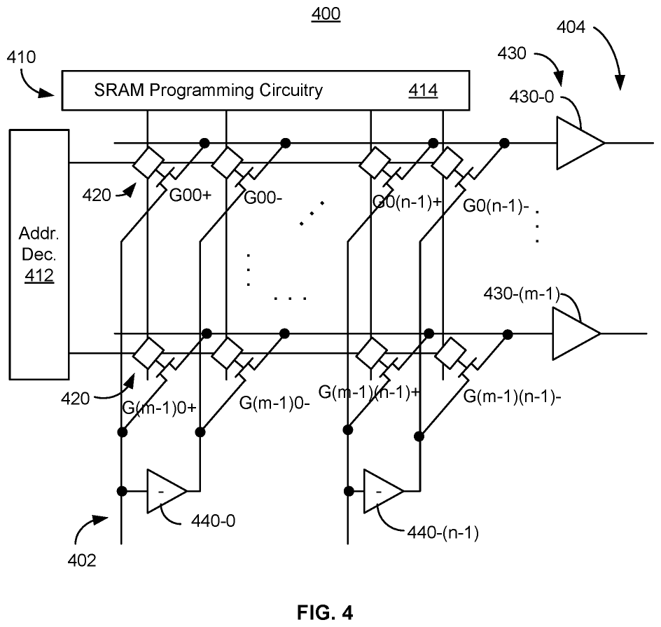

FIG. 4 depicts an embodiment of a system for performing matrix multiplications using resistive SRAM cell(s) in a matrix multiplication network. System 400 is analogous to system(s) 100 and/or 300. Thus, system 400 includes inputs 402, outputs 404, and matrix multiplication network 410 incorporating resistive SRAM cells 420 analogous to inputs 302, outputs 304, and matrix multiplication network 310 incorporating resistive SRAM cells 320. Matrix multiplication network 410 includes address decoder 412, SRAM programming circuitry 414, and output amplifiers 430-0 through 430-(m-1) (collectively or generically 430) analogous to address decoder 312, SRAM programming circuitry 314, and output amplifiers 330. Each resistive SRAM cell 420 may be analogous to resistive SRAM cell 220. Thus, each SRAM cell 420 (of which only two are labeled) may include a number of SRAM cells for storing binary data having a desired number of bits, at least one DAC, and a transistor network analogous to SRAM cells 222, DAC 224, and transistor network 226. The lines corresponding to inputs 402, outputs 404, and resistive SRAM cells 420 may form a crossbar. Thus, matrix multiplication network 410 is a crossbar network. For clarity, in FIG. 4 transistors G00+ through G(m-1)(n-1)− (collectively or generically transistor(s) Gᵢⱼ+ or Gᵢⱼ−) are shown separately from the remainder of resistive SRAM cells 420 (which are indicated by a box). Transistors Gᵢⱼ+ and Gᵢⱼ− may each correspond to transistor 226-0 shown in resistive SRAM cell 220. In addition, Gᵢⱼ+ or Gᵢⱼ− correspond to the effective impedance of the corresponding resistive SRAM cell 420.

Matrix multiplication network 410 is configured for positive and negative values of the matrix. Positive values of a matrix element are stored in a resistive SRAM cell 420 having a transistor labeled with a + (e.g. G00+) while the negative values would be stored in a resistive SRAM cell 420 having a transistor labeled with a − (e.g. G00−). For example, if element 00 of a matrix is positive, element 00 may be stored in resistive SRAM cell having transistor G00+. If element 00 of the matrix is negative, element 00 may be stored in resistive SRAM cell 420 having transistor G00−. Matrix multiplication network 410 also includes analog inverters 440-0 through 440-(n-1) (collectively or generically 440). Thus, each input 402 is provided to both the positive and negative resistive SRAM cells 420. The resistive SRAM cell 420 which stores a nonzero value contributes to the current developed on the corresponding line of the crossbar.

In operation, an input vector is provided via voltage signals over inputs 402. Address decoder 412 activates the lines for resistive SRAM cells 420. The input voltage is provided to the positive resistive SRAM cell 420 (e.g. with transistor Gᵢⱼ+). In contrast, the input voltage provided to the negative resistive SRAM cell 420 (e.g. with transistor Gᵢⱼ-) is inverted by analog inverter 440. The input terminal of output amplifier 420 (e.g. transimpedance amplifier 420) is virtual ground and the applied voltage to each resistive SRAM cell 420 is converted to current through the conductance of the SRAM cell 420. In other words, for a particular resistive SRAM cell 420 the output current I is given by I=(Gᵢⱼ+)V−(Gᵢⱼ−)V, where V is the input signal for column i, Gᵢⱼ+ and Gᵢⱼ− are the effective impedances of the corresponding transistor networks for resistive SRAM cells 420 for matrix element ij. The total current collected at the input of the i^{th} buffer. Hence, the overall system can be written in a matrix form as follows:

$${I}_{t} = {\sum }_{j} ( {G}_{i j}^{+} - {G}_{i j}^{-} ) {V}_{i} = {\sum }_{j} {G}_{i j} {V}_{i}$$

where V is the input vector. Thus, system 400 performs a vector matrix multiplication where the matrix elements may have negative values.

System 400 shares the benefits of systems 100 and 300. Further, system 400 can perform a vector matrix multiplication for a matrix having both positive and negative values. As a result, a vector matrix multiplication may be more rapidly and easily performed.

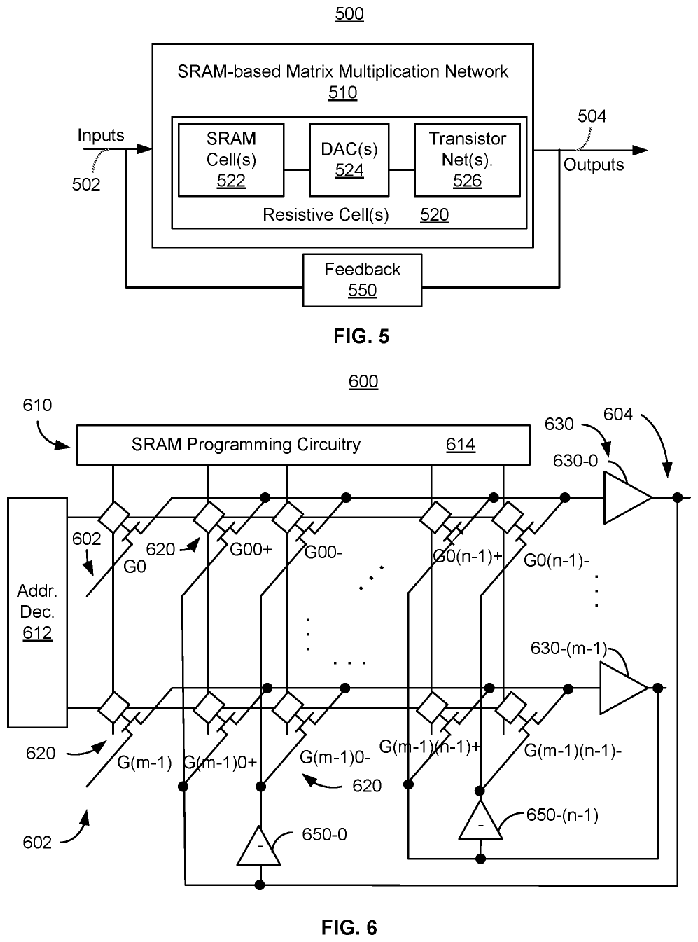

FIG. 5 depicts an embodiment of system 500 for performing matrix multiplications using resistive SRAM cell(s) in a matrix multiplication network. Further, system 500 is configured to provide solutions to a system of equations and/or determine the inverse of the matrix stored. System 500 is analogous to system 100. Thus, system 500 includes inputs 502, outputs 504, and matrix multiplication network 510 incorporating resistive SRAM cell(s) 520 analogous to inputs 102, outputs 104, and matrix multiplication network 110 and resistive SRAM cells 120. SRAM resistive cell(s) 520 include SRAM cell(s) 522, DAC(s) 534, and transistor network(s) 526. Each resistive SRAM cell 520 may be analogous to resistive SRAM cell 220. Thus, a resistive SRAM cell 520 may include a number of SRAM cells for storing binary data having a desired number of bits, at least one DAC, and a transistor network analogous to SRAM cells 222, DAC 224, and transistor network 226.

System 500 also includes feedback 550 between outputs 504 and inputs 502. Although shown as coupled at inputs 502, in some embodiments, feedback network 550 may be coupled in another manner (e.g. to some or all of SRAM resistive cells 520). Feedback network 550 is configured such that system 500 is stable. Thus, in some embodiments, feedback network 550 provides negative feedback of output signals carried on outputs 504 to remaining portion(s) of system 500.

In operation, the elements of an input vector are provided to inputs 502 as input signals. Matrix multiplication network 510 multiplies the vector with the matrix stored in, e.g., resistive SRAM cell(s) 520. The elements of the vector provided to inputs 502 are multiplied with the appropriate elements of the matrix stored in resistive SRAM cell(s) 520. To do so, the binary data stored in SRAM cell(s) 522 is converted, via DAC(s) 524 and transistor network(s) 526, to analog representations of the matrix elements and multiplied by the input signals corresponding to the elements of the input vector. The resulting vector is provided as output signals on outputs 504. The output signals are returned via feedback network 550. Because feedback network 550 provides negative feedback, system 500 is stable and settles rapidly. The output vector X is thus provided on outputs 504 for an input vector B and a matrix A stored in resistive cell(s) 520, where AX=B (or X=A⁻¹B). Thus, system 500 may operate as a solver to the system of equations represented by AX=B.

Using system 500, a vector matrix multiplication in the presence of feedback may rapidly solve a system of equations. Further, if the input vector (B) is a column of the identity matrix, system 500 may be used to rapidly determine the inverse (A⁻¹) of the stored matrix A. For example, if the stored matrix has n columns, then the n columns of the identity matrix may be individually provided to inputs 502. After system 500 settles, the output vector provided on outputs 504 is a column of the inverse of the stored matrix. After n iterations, the inverse of the stored matrix is known. Consequently, system 500 also allows for a relatively simple and fast determination of the inverse of the matrix stored in matrix multiplication network 510. Because of the use of SRAM cell(s) 522, system 500 also has improved scalability, case of manufacture, and shorter programming time.

FIG. 6 depicts an embodiment of system 600 for performing matrix multiplications using resistive SRAM cell(s) in a matrix multiplication network. System 600 is analogous to system 500 as well as to system 400. More specifically, system 600 allows for solutions of a system of equations as well as a matrix in which both positive and negative values may be present.

System 600 includes inputs 602, outputs 604, and matrix multiplication network 610 incorporating resistive SRAM cells 620 that are analogous to inputs 402 and 502, outputs 404 and 504, and matrix multiplication networks 410 and 510 incorporating resistive SRAM cells 420 and 520. Matrix multiplication network 610 includes address decoder 612, SRAM programming circuitry 614, and output buffers 630-0 through 630-(m-1) (collectively or generically output buffers 630) analogous to address decoder 412, SRAM programming circuitry 414, and output amplifiers 430. Each resistive SRAM cell 620 may be analogous to resistive SRAM cell 220 and/or 420. Thus, each SRAM cell 620 may include a number of SRAM cells for storing binary data having a desired number of bits, at least one DAC, and a transistor network analogous to SRAM cells 222, DAC 224, and transistor network 226. The lines corresponding to inputs 602 and outputs 604 and resistive SRAM cells 620 may form a crossbar. Thus, matrix multiplication network 610 is a crossbar network. For clarity, in FIG. 6 transistors G00+ through G(m-1)(n-1)−(collectively or generically transistor(s) Gᵢⱼ+ or Gᵢⱼ−) are shown separately from the remainder of resistive SRAM cells 620 (which are indicated by a box). Transistors Gᵢⱼ+ and Gᵢⱼ− may each correspond to transistor 226-0 shown in resistive SRAM cell 220. In addition, Gᵢⱼ+ or Gᵢⱼ− correspond to the effective impedance of the resistive SRAM cell 620. The resistive SRAM cells 620 having impedances Gᵢⱼ+ and Gᵢⱼ− store the matrix corresponding to the system of equations to be solved.

Also included in matrix multiplication network 610 are resistive SRAM cells 620 having transistors Go through G(m-1). These SRAM cells 620 are coupled to the corresponding output lines 604 as well as input lines 602. System 600 also has feedback including feedback buffers 650-0 through 650-(n-1) (collectively or generically 650) that is analogous to feedback 550. Output buffers 630 as well as feedback buffers 650 may be configured to have zero input current. Matrix multiplication network 610 is configured for positive and negative values of the matrix in a manner analogous to matrix multiplication network 410. In addition, feedback is provided from outputs 604 to the inputs of positive and negative resistive SRAM cells 620. In the embodiment shown, output buffers 630 are positive output buffers (e.g. positive transimpedance amplifiers), while feedback buffers 650 are negative feedback buffers 650 (e.g. negative feedback operational amplifiers). Although not shown, switches may be included to selectively decouple feedback between outputs 604 and inputs. In such a case, system 600 may provide a vector matrix multiplication of the stored matrix when the feedback is decoupled. System 600 may provide a vector matrix multiplication of the inverse of the stored matrix when the feedback is coupled.

In operation, an input vector, B, is provided via inputs 602. Address decoder 612 activates the lines for resistive SRAM cells 620. The positive and negative matrix values have been programmed to positive and negative resistive SRAM cells 620 (e.g. with transistors Gᵢⱼ+ and Gᵢⱼ−) by SRAM programming circuitry 614. The appropriate values have been programmed into resistive SRAM cells 620 (e.g. with transistors G₀ through Gₘ₋₁). Currents corresponding to the input voltages are provided from resistive SRAM cells 620 having with transistors G₀ through Gₘ₋₁ are provided to output buffers 630. The output signals from output buffers 630 are fed back to the corresponding columns.

The input current to the input terminal of output buffers 630 is zero. The voltage applied to each resistive SRAM cell 620 is converted to current through the conductance of the resistive SRAM cell 620. The total current, Iₜ, collected at the input of the i^{th} output buffer 630-i is:

$${I}_{t} = {G}_{i} {B}_{i} + {\sum }_{j} ( {G}_{i j}^{+} - {G}_{i j}^{-} ) {V}_{i} = 0$$

where Vᵢ is i^{th} component of the voltage vector, V, output by output buffers 630 (and fed back via the feedback network including feedback amplifiers 650) and Bᵢ is the i^{th} component of an input vector B provided to inputs 602. Suppose −GᵢBᵢ is defined as Yᵢ. Thus, Y is simply the input voltage vector B converted to current. Hence, the overall system can be written in a matrix form as Iₜ=−Y+GV=0. In other words, GV=Y. As a result, the output voltage, V, can be written as: V=G⁻¹Y. Thus, the output signals provided on outputs 604 are the solution to the equation GV=Y. Consequently, the output voltage solves the system of equations.

System 600 shares the benefits of system 500. Using system 600, a vector matrix multiplication in the presence of feedback may rapidly solve a system of equations. Further, if the input vector (B) is a column of the identity matrix, system 600 may be used to rapidly determine the inverse (G-1) of the stored matrix G. Consequently, system 500 also allows for a relatively simple and fast determination of the inverse of the matrix stored in matrix multiplication network 610. Because of the use of resistive SRAM cell(s) 620, system 600 also has improved scalability, ease of manufacture, and programming time.

For example, the conductances of a portion of a circuit may be stored in resistive SRAM cells 620. The conductances may be for weights in a neural network. The conductances may be for an arbitrary circuit (e.g. a layer in a neural network, a neural network, or another circuit) determined via modified nodal analysis (MNA), described below. Using system 600, the inverse of the conductance matrix may be determined. This inverse may be used in performing backpropagation for the neural network or for other purposes.

Although an embodiment of system 500 is described in the context of system 600 having a crossbar, system 500 need not be configured as a crossbar. For example, system 500 may be any electrical network (e.g. a circuit) describable in terms of a matrix. In some cases, matrix multiplication network 510 may instead be or include one or more layers of a neural network. For example, network 510 could be a weight layer of a neural network or multiple layers (e.g. neuron layers interleaved with weight layers) of a neural network. Matrix multiplication network 510 may be another circuit/network including a combination of resistors, transistors, diodes, and/or analogous components. Such a network has a conductance parameterization. For example, modified nodal analysis (MNA) may be used to provide a conductance parameterization of a network. MNA is a technique that predicts behavior (e.g. the operating point) of a network (e.g. a circuit) by representing nodes in an electrical circuit using voltages, conductances, and currents. MNA also utilizes a linearized circuit. For example, a nonlinear component such as a diode at particular operating conditions may be represented by a linear resistor that has the resistance of the diode connected in parallel with a current source at the particular operating conditions.

A larger circuit (e.g. system 500) may be built by adding to the original circuit (corresponding to matrix multiplication network 510). The larger circuit may be formed by adding negative feedback such as negative feedback operational amplifiers (corresponding to feedback 550) between the outputs 504 and inputs 502 of the original circuit (corresponding to matrix multiplication 510). The conductance matrix, G, of the original circuit is desired to be inverted. This may be accomplished by injecting currents, B, at the output ports of the modified circuit. This results in the solution, X, to GX=B. Thus, the inverse of the conductance matrix and the solution to the inputs required for given outputs may be determined.

For example, suppose G is the effective conductance matrix of an arbitrary circuit. Such a conductance matrix may have the form:

$$\begin{matrix}{G}_{11} & {G}_{12} \\ {G}_{21} & {G}_{22}\end{matrix}$$

The input-output transfer function (output signals for a given set of input signals) is given by the submatrix G₁₂=A (the matrix desired to be inverted). M is the total MNA matrix of G in the larger circuit including the original circuit connected with the feedback operational amplifiers. Thus, M is given by:

$$\begin{matrix}{G}_{11} & {G}_{12} & I \\ {G}_{21} & {G}_{22} & 0 \\ 0 & - I & 0\end{matrix}$$

By applying a current vector [0, b, 0] to M⁻¹ the resultant voltage at the input nodes may be obtained. Stated differently, applying b to the outputs computes the solution vector x=(G₂₁)⁻¹b. Although described in the context of operational amplifiers, resulting in the identity matrix and the negative of the identity matrix, this process can be used for the feedback circuitry being described by any invertible matrix (as opposed to the identity matrix). For example, a network of resistors may be used as the feedback or with the operational amplifier as part of the feedback. Thus, the use of system 500 (and system 600) may be extended beyond the use of crossbars.

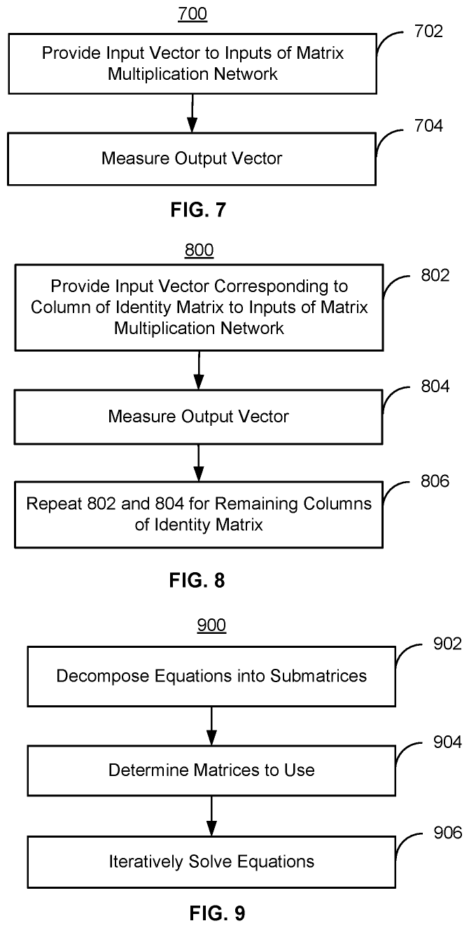

FIG. 7 is a flow chart depicting an embodiment of method 700 for performing matrix multiplications using resistive SRAM cell(s) in a matrix multiplication network. For simplicity, only some steps are shown. Further, method 700 is described in the context of systems 300, 400, and 600. However, other systems analogous to systems 100, 300, 400, 500, and/or 600 may be used.

An input vector corresponding to the vector desired to be multiplied is provided to the inputs of a matrix multiplication network, at 702. The matrix multiplication network stores, in resistive SRAM cells, the matrix desired to be used for the matrix multiplication. The output vector is read on the outputs, at 704.

For example, in system 300, the input voltage signals for the elements of the vector desired to be multiplied are provided to inputs 302, at 702. Resistive SRAM cells 320 store binary data for elements of the matrix desired to be multiplied. The corresponding conductances for resistive SRAM cells 320 result in currents provided to transimpedance amplifiers 330. The output voltage signals developed on outputs 304 may be measured, at 704. Thus, the vector matrix multiplication may be performed.

In another example, in system 400, the input voltage signals for the elements of the vector desired to be multiplied are provided to inputs 402, at 702. Resistive SRAM cells 420 store the binary data for the positive or negative values of the elements of the matrix desired to be multiplied. The corresponding conductances for resistive SRAM cells 420 results in currents provided to transimpedance amplifiers 430. The output voltage signals developed on outputs 404 may be measured, at 704. Thus, the vector matrix multiplication may be performed for a matrix having positive or negative values. Thus, using method 700 a vector matrix multiplication may be rapidly and easily performed.

Method 700 may also be used to perform a vector matrix multiplication that results in the solution to a system of equations. In such an embodiment, the input voltage signals for the elements of the vector that is the resulting and for which the solution is desired are provided to inputs 602, at 702. Resistive SRAM cells 620 store the binary data for the positive or negative values of the elements of the matrix corresponding to the system of equations. Thus, the input vector is desired to be multiplied by the inverse of the stored matrix. Feedback including feedback amplifiers 650 route the output signals back to inputs of resistive SRAM cells 620. The corresponding conductances for resistive SRAM cells 620 results in currents provided to transimpedance amplifiers 630. System 600 is allowed to settle and the output voltage signals developed on outputs 604 may be measured, at 704. The output voltage signals measured at outputs 604 correspond to X, where B is the input vector provided to inputs 602, A is the stored matrix in matrix multiplication network 610, and AX=B. Thus, the solution of a system of equations described by an equation including a matrix having positive or negative values may be readily obtained.

FIG. 8 is a flow chart depicting an embodiment of a method for performing a matrix inversion using resistive SRAM cell(s) in a matrix multiplication network. For simplicity, only some steps are shown. Further, method 800 is described in the context of system 600. However, other systems analogous to systems 500 and/or 600 may be used.

An input vector corresponding to a column in the identity matrix is provided to the inputs of a matrix multiplication network including feedback, at 802. The matrix multiplication network stores, in resistive SRAM cells, the matrix desired to be inverted. The system is allowed to settle and the output vector is read on the outputs, at 804. At 806, 802 and 804 are repeated for the remaining columns of the identity matrix corresponding to the matrix to be inverted.

For example, in system 600, the input voltage signals for the elements of the first column in the identity matrix (1, 0, 0, . . . 0) are provided to inputs 602, at 802. Resistive SRAM cells 620 store binary data for elements of the matrix desired to be inverted. Feedback including feedback amplifiers 650 route the output signals back to inputs of resistive SRAM cells 620. The corresponding conductances for resistive SRAM cells 620 results in currents provided to transimpedance amplifiers 630. System 600 is allowed to settle and the output voltage signals developed on outputs 604 may be measured, at 804. This corresponds to the first column in the inverse of the matrix.

At 806, the input voltage signals for the elements of the first column in the identity matrix (0, 1, 0, . . . 0) are provided to inputs 602, at 802. Resistive SRAM cells 620 store binary data for elements of the matrix desired to be inverted. Feedback including feedback amplifiers 650 route the output signals back to inputs of resistive SRAM cells 620. The corresponding conductances for resistive SRAM cells 620 results in currents provided to transimpedance amplifiers 630. System 600 is allowed to settle and the output voltage signals developed on outputs 604 may be measured, at 804. This corresponds to the second column in the inverse of the matrix. This process continues for each column in the identity matrix. Thus, the inverse of the matrix stored may be readily obtained.

FIG. 9 is a flow chart depicting an embodiment of 900 method for performing matrix multiplications using resistive SRAM cell(s) in a matrix multiplication network. More specifically, method 900 may be used to determine the solution to a system of equations where the matrix in the equations is too large to be completely stored in the system. For simplicity, only some steps are shown.

The matrix corresponding to the equations is decomposed into submatrices which are storable in the corresponding system, at 902. The appropriate matrices-either the submatrix from the system of equations or an inverse-usable in solving the system of equations is determined, at 904. These matrices may also be stored at 904. The equations are iteratively solved, at 906.

For example, a system of equations Ax=b may be represented by:

$$[ \begin{matrix}{A}_{11} & {A}_{12} \\ {A}_{21} & {A}_{22}\end{matrix} ] [ \begin{matrix}{x}_{1} \\ {x}_{2}\end{matrix} ] = [ \begin{matrix}{b}_{1} \\ {b}_{2}\end{matrix} ]$$

Thus, at 902, the matrices A₁₁, A₁₂, A₂₁, A₂₂ may be determined. The solution can be given by:

$${x}_{1} = {A}_{11}^{- 1} {b}_{1} - {A}_{11}^{- 1} {A}_{12} {x}_{2}$$

$${x}_{2} = {A}_{22}^{- 1} {b}_{2} - {A}_{22}^{- 1} {A}_{21} {x}_{1}$$

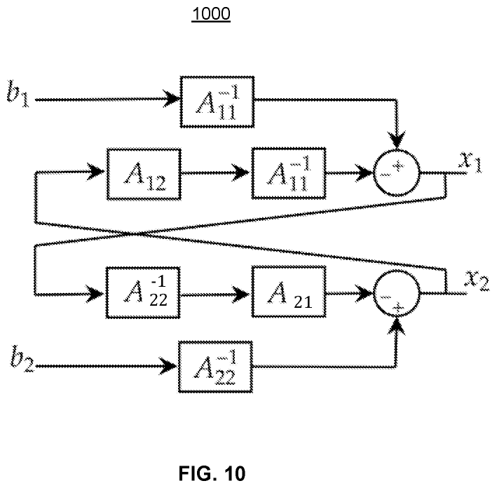

The system may be configured to implement this solution iteratively. Thus, the matrices A₁₂, A₂₁, A₁₁⁻¹, and A₂₂⁻¹ may be determined at 904. FIG. 10 depicts a block diagram of an embodiment system 1000 for performing matrix multiplications that can iteratively solve the above equations. In the embodiment shown, matrices A₁₂, A₂₁, A₁₁⁻¹, and A₂₂⁻¹ may be provided in interconnected systems, such as systems 100, 300, 400, and 600 in order to perform the appropriate vector matrix multiplications. In some embodiments, the system 1000 may be stored at 904. The vectors b1 and b2 may be input to system 1000 and system 1000 allowed to settle. System 1000 may settle to a solution within a few cycles. Thus, x₁ and x₂ may be determined via 906. As a result, a large system of equations may be rapidly and readily solved.

Although the foregoing embodiments have been described in some detail for purposes of clarity of understanding, the invention is not limited to the details provided. There are many alternative ways of implementing the invention. The disclosed embodiments are illustrative and not restrictive.

What is claimed is:

1. A resistive cell, comprising:
a plurality of static random access memory (SRAM) cells having a multi-bit state;
a digital-to-analog converter (DAC) that converts the multi-bit state to an analog signal; and
a transistor network receiving the analog signal as an input and providing a digitally controlled conductance;
wherein the resistive cell is integrated into a matrix multiplication network.

2. The resistive cell of claim 1, wherein a gate of a transistor in the transistor network is coupled to a DAC output of the DAC that provides the analog signal to the gate such that the analog signal controls the digitally controlled conductance.

3. The resistive cell of claim 1, wherein the matrix multiplication network represents a matrix, the matrix including a modified nodal analysis (MNA) matrix for a corresponding network, the plurality of SRAM cells storing a conductance for the MNA matrix of a component in the corresponding network.

4. The resistive cell of claim 3, wherein the matrix multiplication network further includes a plurality of inputs, a plurality of outputs, and feedback between the plurality of outputs and the plurality of inputs, and wherein a portion of the matrix corresponds to the feedback and is an invertible matrix.

5. The resistive cell of claim 4, wherein the corresponding network is a layer of a neural network including a plurality of layers, the layer including a weight layer.

6. The resistive cell of claim 1, wherein the matrix multiplication network includes a crossbar network, the resistive cell being at a crossing point of the crossbar network.

7. The resistive cell of claim 6, wherein the matrix multiplication network further includes a plurality of resistive cells, each of the plurality of resistive cells corresponding to the resistive cell and being located at a plurality of remaining crossing points of the crossbar network.

8. The resistive cell of claim 7, wherein the matrix multiplication network further includes a plurality of inputs to the crossbar network, a plurality of outputs from the crossbar network, and a plurality of negative feedback networks coupling the plurality of outputs with the plurality of inputs, the plurality of negative feedback networks being represented by at least one invertible matrix.

9. The resistive cell of claim 8, wherein the plurality of negative feedback networks includes a plurality of operational amplifiers.

10. A system, comprising:
a plurality of inputs;
a plurality of resistive cells, each of the plurality of resistive cells including a plurality of static random access memory (SRAM) cells having a multi-bit state, a digital-to-analog converter (DAC) that converts the multi-bit state to an analog signal, and a transistor network receiving the analog signal as an input and providing a digitally controlled conductance; and
a plurality of outputs, the plurality of resistive cells being coupled between the plurality of inputs and the plurality of outputs;
wherein the plurality of inputs, the plurality of outputs and the plurality of resistive cells are configured as a matrix multiplication network.

11. The system of claim 10, wherein the matrix multiplication network represents a matrix, wherein the multi-bit state of each of at least a portion of the plurality of resistive cells corresponds to a conductance in a modified nodal analysis (MNA) matrix for a corresponding network.

12. The system of claim 11, wherein the matrix multiplication network further includes feedback between the plurality of outputs and the plurality of inputs, and wherein a portion of the matrix corresponds to the feedback and is an invertible matrix.

13. The system of claim 12, wherein the corresponding network is a layer of a neural network including a plurality of layers, the layer including a weight layer.

14. The system of claim 10 wherein the plurality of resistive cells is coupled as a crossbar network, each of the plurality of resistive cells being at a crossing point of a plurality of crossing points of the crossbar network.

15. The system of claim 14 further comprising:
a plurality of inverters coupled between a portion of adjacent columns of the crossbar network, the plurality of inverters corresponding to negative elements.

16. The system of claim 14, further comprising:
a plurality of negative feedback networks coupled between the plurality of outputs and the plurality of inputs, the plurality of negative feedback networks being represented by at least one invertible matrix.

17. A method, comprising:
providing an input vector to a plurality of inputs of a matrix multiplication network, the matrix multiplication network including the plurality of inputs, a plurality of resistive cells, and a plurality of outputs, the plurality of resistive cells being coupled between the plurality of inputs and the plurality of outputs, each of the plurality of resistive cells including a plurality of static random access memory (SRAM) cells having a multi-bit state, a digital-to-analog converter (DAC) that converts the multi-bit state to an analog signal, and a transistor network receiving the analog signal as an input and providing a digitally controlled conductance; and
measuring, at the plurality of outputs, an output vector, the output vector being a product of a matrix and the input vector.

18. The method of claim 17 wherein the plurality of resistive cells is coupled as a crossbar network, each of the plurality of resistive cells being at a crossing point of a plurality of crossing points of the crossbar network.

19. The method of claim 18, wherein the matrix multiplication network further includes a plurality of feedback networks coupled between the plurality of inputs and the plurality of outputs, wherein the multi-bit state of each of the plurality of resistive cells corresponds to an element of the matrix, and wherein the output vector solves a system of equations represented by AX=B, where A is the matrix and B is the input vector.

20. The method of claim 18, wherein the matrix multiplication network further includes a plurality of feedback networks coupled between the plurality of inputs and the plurality of outputs, wherein the multi-bit state of each of the plurality of resistive cells corresponds to an element of the matrix, wherein the input vector is one of a plurality of input vectors, the method further comprising:
repeating the providing and measuring for each remaining vector of the plurality of input vectors, each of the plurality of input vectors corresponding to a column in an identity matrix.
